(19) United States
(12) Patent Application Publication
(10) Pub. No.: US 2026/0340224 A1
(43) Pub. Date: Oct. 29, 2026

(54) RECOGNITION-COVERAGE EARLY-RADIATION TAIL PREDICTOR - DETERMINISTIC Delta N_eff GENERATOR FOR COSMOLOGY PIPELINES

(71) Applicant: Jonathan Washburn, Austin, TX (US)

(72) Inventor: Jonathan Washburn, Austin, TX (US)

(21) Appl. No.: 19/651,191

(22) Filed: Apr. 17, 2026

Related U.S. Application Data
(60) Provisional application No. 63/794,573, filed on Apr. 25, 2025.

(51) Int. Cl. G06F 30/20

(52) U.S. Cl. CPC G06F 30/20

(57) ABSTRACT

A computer-implemented synthesis architecture generates a unitary flavor-mixing matrix from fixed integer ladder assignments through deterministic phase assignment and unitary completion. For paired source and target states, ladder-index differences are determined, and raw matrix-element magnitudes are computed as mag_ij=X_opt\hat{ }(abs(Delta_n_ij)/4), where X_opt=phi/pi in a disclosed embodiment. Complex phases are then assigned under a deterministic phase-gauge rule to form a complex provisional matrix, which is unitarised to produce a CKM or PMNS matrix. In preferred embodiments, determinant-preserving and sign-preserving control are applied during phase assignment and unitary completion, and Gram-Schmidt orthonormalisation is used. The same exact magnitude rule may be used for CKM and PMNS synthesis with different fixed ladder tables.

### CROSS-REFERENCE TO RELATED APPLICATIONS

This application claims the benefit of U.S. Provisional Patent Application No. 63/794,573, filed on Apr. 25, 2025, the entire contents of which are incorporated herein by reference to the extent permitted by law.

### BACKGROUND OF THE INVENTION

The present disclosure relates generally to precision-cosmology software, cosmological parameter estimation, Boltzmann-code execution, and machine-implemented provision of effective radiation-content parameters. More particularly, the present disclosure relates to deterministic generation and provision of a fixed Delta N_eff value for use in cosmology pipelines, including local software embodiments, direct solver-integration embodiments, machine-readable output embodiments, and optional service and accelerator embodiments.

In modern cosmology, the effective number of neutrino species, N_eff, parameterizes total relativistic radiation content in the early universe. In common usage, total radiation content may be expressed as N_eff_total=N_eff_SM+Delta N_eff, where N_eff_SM corresponds to the Standard Model contribution and Delta N_eff corresponds to any additional effective radiation contribution. In the disclosed materials, N_eff_SM is taken as 3.044.

In conventional cosmology workflows, including workflows implemented through Boltzmann solvers and parameter-estimation engines such as CAMB, CLASS, CosmoMC, and related tools, Delta N_eff is often treated as a free parameter. In such workflows, Delta N_eff is sampled in Markov chain Monte Carlo chains and marginalized over in posterior estimation. This increases chain dimensionality, increases repeated solver execution, and increases the computational burden associated with evaluating cosmological observables over many candidate values.

For each sampled Delta N_eff value, a solver may recompute one or more outputs such as CMB temperature spectra, CMB polarization spectra, matter power spectra, baryon acoustic oscillation quantities, or related observables. As a result, the free-parameter treatment of Delta N_eff can add computational expense and can introduce variation across analyses when different groups or pipelines adopt different assumptions, priors, sampled ranges, or posterior treatments for Delta N_eff.

Accordingly, a need exists for a deterministic, reproducible, machine-suppliable Delta N_eff source that can replace a sampled free-parameter axis in cosmology computation. A need further exists for architectures that can compute, store, retrieve, embed, or otherwise supply such a fixed Delta N_eff value to cosmology software in a form usable by solvers, parameter-estimation chains, forecast engines, and related systems.

The present disclosure addresses these and other needs by providing a deterministic effective-radiation contribution defined by a closed-form relation and by providing implementation architectures for supplying that fixed contribution to cosmology computation in place of a sampled or marginalized Delta N_eff parameter.

### SUMMARY OF THE INVENTION

The present disclosure provides a deterministic effective-radiation contribution for cosmology computation, wherein the contribution is given by the closed-form relation Delta N_eff=X_opt\hat{ }(7/3)=(phi/pi)\hat{ }(7/3), with X_opt=phi/pi. The resulting value is fixed and may be supplied to cosmology computation as a non-sampled, non-marginalized, and non-posterior-dependent input in place of a free Delta N_eff parameter. In a preferred numerical embodiment, Delta N_eff is approximately 0.212628491279.

In one aspect, the disclosure provides a machine-implemented method comprising determining or storing X_opt, determining or storing Delta N_eff according to Delta N_eff=X_opt\hat{ }(7/3), optionally determining N_eff_total=3.044+Delta N_eff, supplying Delta N_eff and/or N_eff_total to a cosmology solver, forecast engine, or parameter-estimation engine, and executing a computation using the fixed value in place of a sampled Delta N_eff parameter.

In another aspect, the disclosure provides a software embodiment in which the fixed Delta N_eff value is exposed through a local library, callable function, package, configuration object, initialization artifact, or solver patch artifact. In preferred embodiments, the deterministic value is integrated into CAMB, CLASS, or related cosmology computation systems such that the value replaces a free parameter that would otherwise be sampled or marginalized.

In another aspect, the disclosure provides a system comprising one or more processors and one or more memory devices storing instructions that cause the system to compute, store, retrieve, or output the disclosed fixed Delta N_eff value and to provide that value to a cosmology computation engine. The engine may comprise a Boltzmann solver, MCMC-based parameter-estimation engine, cosmology forecast engine, or related computation pipeline.

In another aspect, the disclosure provides optional machine-readable and deployment embodiments, including service-based embodiments, network-response embodiments, fixed-point embodiments, and accelerator embodiments. In such embodiments, the core mathematical relation remains the same, while the implementation class may vary. Optional service embodiments may expose the fixed value through REST, gRPC, or other interfaces and may return a machine-readable response object including one or more of a Delta N_eff field, an N_eff_total field, a formula field, an X_opt field, and a precision field. Optional hardware embodiments may store or output the fixed value in CPU, fixed-point, FPGA, ROM, or related hardware forms, including embodiments in which the value is represented in fixed-point form and provided by FPGA logic. In representative workflow embodiments, use of the disclosed fixed value in place of a sampled Delta N_eff parameter may support a reduced-dimension computation path, including reduction of a parameter-estimation workflow from a 7-parameter chain including Delta N_eff to a 6-parameter chain in which Delta N_eff is not independently sampled. These implementation classes and workflow consequences are subordinate to the core invention, which remains the deterministic provision of the disclosed Delta N_eff value and its use in place of a free Delta N_eff parameter.

In preferred embodiments, the disclosure further provides N_eff_total output for systems that accept total N_eff rather than Delta N_eff directly. In one disclosed embodiment, N_eff_total is 3.044+0.212628491279, which is approximately 3.256628491279.

In preferred embodiments, the disclosure also preserves formal support for the closed-form relation and associated properties, including machine-checked formal verification of the relation, positivity, boundedness, numeric realization, and parameter-free status as described in the source materials. Such formal verification supports written description, exactness of disclosure, and fallback claim strategy, while not being required in the broadest embodiments unless expressly recited.

In downstream embodiments, the disclosed deterministic value may be used in CMB parameter estimation, BAO forecasting, damping-tail comparison, cross-code reproducibility workflows, and related cosmological analysis tasks. In prophetic embodiments, the disclosed framework may be extended to temperature-dependent Delta N_eff(T), species decomposition, joint forecasting with tensor-to-scalar or lensing modules, and dedicated hardware families. Such downstream and prophetic embodiments remain subordinate to the core invention.

The disclosure therefore provides a deterministic, fixed, closed-form, and parameter-free Delta N_eff generator and associated implementation architectures that replace a free Delta N_eff parameter axis in cosmology computation with a machine-suppliable constant derived from the disclosed relation.

### BRIEF DESCRIPTION OF THE DRAWINGS

FIG. 1 is a high-level block diagram of a deterministic Delta N_eff generator and cosmology pipeline architecture, showing derivation of X_opt, application of the exponent relation, generation of a fixed Delta N_eff value, optional generation of total N_eff, and supply of the resulting value to cosmology computation components.

FIG. 2 is a derivation-flow diagram showing computation of X_opt from phi and pi, determination of the exponent ratio, generation of Delta N_eff according to Delta N_eff=X_opt\hat{ }(7/3), optional generation of N_eff_total, and optional production of associated metadata.

FIG. 3 is a software-implementation diagram showing a library embodiment, a callable function embodiment, a stored-constant embodiment, patch-generation embodiments for cosmology solvers, configuration or initialization artifact generation, and patched solver execution.

FIG. 4 is a workflow diagram showing replacement of a sampled Delta N_eff branch in a conventional cosmology parameter-estimation workflow with a deterministic fixed-value branch, thereby supporting a reduced-dimension computation path and associated reproducibility and compute-efficiency outputs.

FIG. 5 is a diagram of an optional network-service embodiment for deterministic value provision, including request handling, one or more interface types, deterministic value generation or retrieval, response formatting, and optional authentication or rate-management functions.

FIG. 6 is a diagram of an optional hardware and fixed-point embodiment, including a host processor, constant storage, optional arithmetic logic, optional FPGA or ROM-based implementation, and output delivery to a downstream compute consumer.

FIG. 7 is a diagram showing downstream cosmology applications of the deterministic generator output, including CMB analysis, BAO forecasting, damping-tail comparison, cross-code comparison, reproducibility analysis, and validation reporting, all of which are subordinate to the core deterministic generator.

FIG. 8 is a diagram showing demonstrated and prophetic validation pathways, including implemented computational examples, solver-integration examples, cross-code comparison, future observational testing pathways, and classification of support levels distinguishing demonstrated material from prophetic material.

### DETAILED DESCRIPTION OF THE INVENTION

Reference will now be made in detail to various embodiments of the disclosed subject matter, examples of which are illustrated in the accompanying drawings. Wherever possible, the same reference numerals are used throughout the drawings and the following description to refer to the same or like parts. The drawings are provided to illustrate representative embodiments and implementation classes of the invention and are not intended to limit the scope of the claims. Unless expressly stated otherwise, the invention is the deterministic provision of the disclosed Delta N_eff value and the use of that value in place of a sampled or marginalized free Delta N_eff parameter in cosmology computation.

As discussed above, the core invention is not a generic cosmology platform, not a generic cloud service, and not all of Recognition Science. Rather, the invention is the specific deterministic provision of a fixed early-radiation contribution defined by the closed-form relation Delta N_eff=X_opt\hat{ }(7/3)=(phi/pi)\hat{ }(7/3), with X_opt=phi/pi, and the operational use of that fixed value in place of a sampled, marginalized, or posterior-dependent Delta N_eff parameter in cosmology software. Preferred, optional, downstream, and prophetic embodiments are disclosed to preserve implementation flexibility without changing that core identity.

All disclosed embodiments share a common inventive concept: a deterministic fixed-value substitution mechanism that causes a cosmology computation system to use the disclosed Delta N_eff (or N_eff_total derived therefrom) as a fixed input in place of sampling or marginalizing Delta N_eff as an independent parameter axis. Service, patch, configuration, library, and hardware embodiments are alternative implementation classes for supplying the same fixed-value substitution to the same class of cosmology computations.

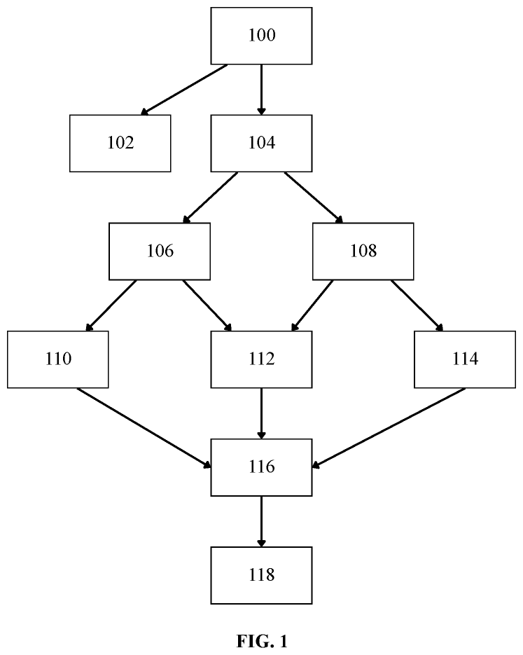

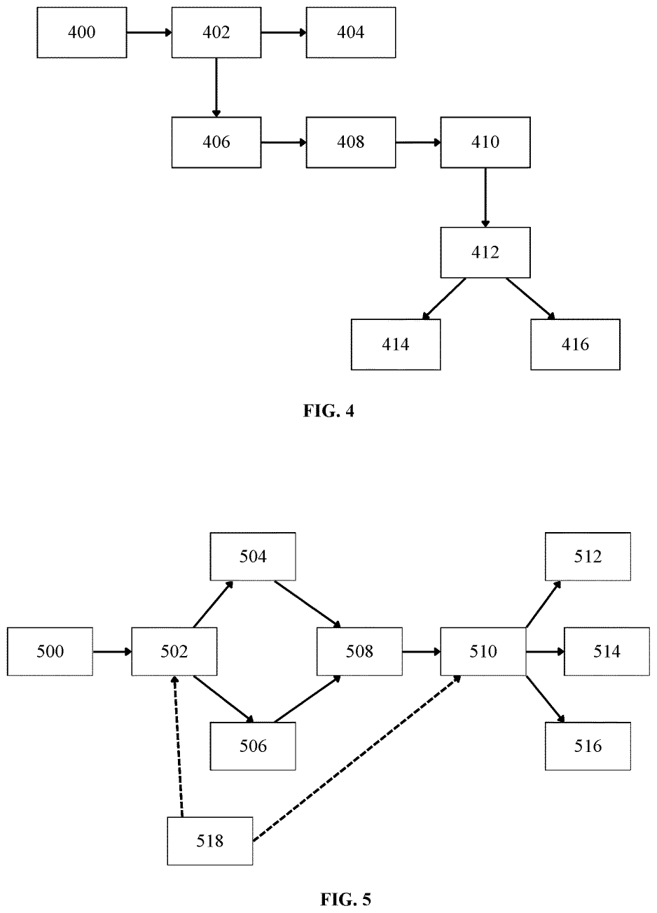

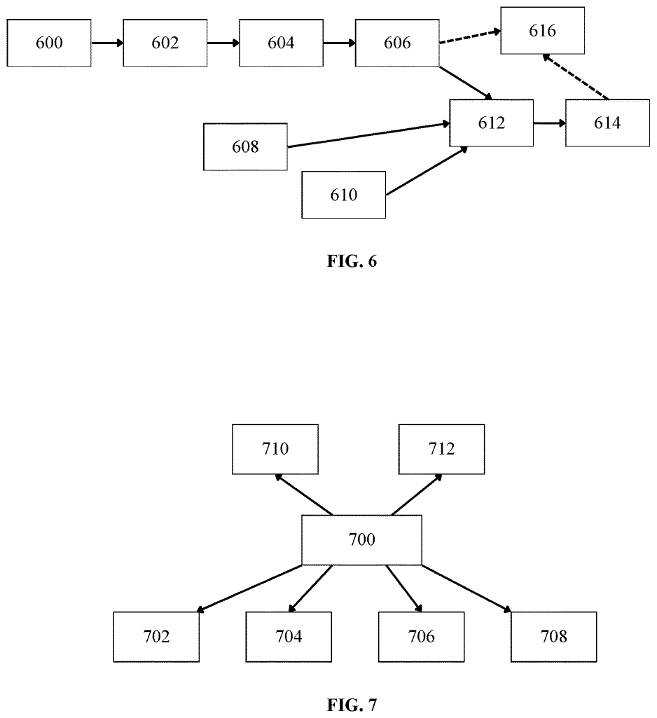

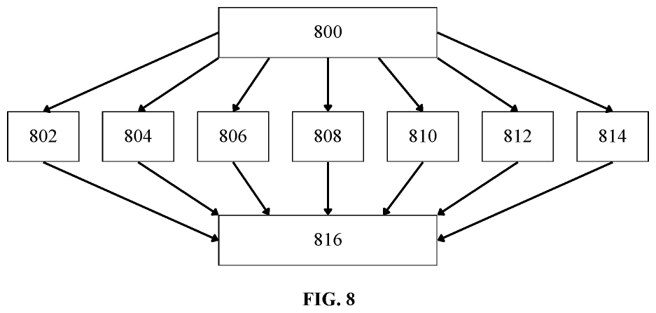

In the illustrated embodiments, FIGS. 1-4 primarily depict the core deterministic Delta N_eff generation and substitution architecture. FIGS. 5-6 depict optional implementation classes, including optional service and hardware embodiments. FIGS. 7-8 depict subordinate downstream, validation, and support-level embodiments. Accordingly, the figures should be understood as illustrating different levels of embodiment support while preserving the identity of the core invention as the deterministic provision of the disclosed Delta N_eff value and the use of that value in place of a sampled or marginalized free Delta N_eff parameter in cosmology computation.

Referring first to FIG. 1, a high-level deterministic Delta N_eff generator and cosmology pipeline architecture is shown. Deterministic generator 100 may include X_opt derivation block 102 (computing X_opt=phi/pi), exponent application block 104 (applying the disclosed exponent relation to obtain Delta N_eff), fixed Delta N_eff output 106, and optional N_eff_total output 108. Generator 100 may communicate through local software interface 110 (e.g., library call or configuration), network interface 112 (e.g., REST or gRPC response), or solver integration interface 114 (e.g., patch, initialization file, or runtime parameter insertion) with cosmology computation engine 116, which produces result output module 118. FIG. 1 therefore illustrates the invention at the correct level of abstraction: the disclosed relation is used to generate or provide a fixed Delta N_eff value, and that fixed value is supplied to cosmology computation in place of a sampled free parameter.

In the embodiment of FIG. 1, X_opt derivation block 102 determines X_opt according to X_opt=phi/pi. Exponent application block 104 applies the disclosed exponent relation to determine Delta N_eff according to Delta N_eff=X_opt\hat{ }(7/3). Fixed Delta N_eff output 106 may then be supplied directly to a target computation, while optional N_eff_total output 108 may be supplied where a target system accepts total N_eff rather than Delta N_eff directly. Local software interface 110 may include a callable library, package, SDK, command-line tool, or other local interface. Network interface 112 may include optional service-based delivery. Solver integration interface 114 may include patch generation, configuration generation, initialization-file generation, or direct runtime parameter insertion. Cosmology computation engine 116 may comprise a Boltzmann solver, MCMC engine, forecast engine, or other cosmology computation pipeline.

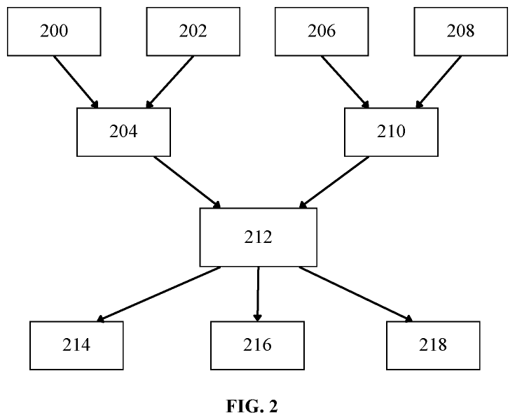

Referring to FIG. 2, a derivation and numerical realization flow is shown. Phi input 200 and pi input 202 are received by X_opt computation block 204, which determines X_opt=phi/pi. g_R input 206 and D input 208 are processed by exponent ratio block 210, which provides the exponent relation used by Delta N_eff computation block 212. Fixed-decimal representation block 214 stores or outputs a convenient decimal embodiment of the disclosed value. N_eff_total computation block 216 optionally determines total N_eff by adding the baseline Standard Model contribution. Metadata generation block 218 may optionally produce formula information, X_opt information, precision information, or other machine-readable descriptors.

FIG. 2 is especially useful for preserving the determinative derivation structure disclosed in the source materials. In the disclosed framework, the exponent 7/3 corresponds to g_R/D, where g_R=7 and D=3. The disclosed framework presents this exponent relation as determinative rather than as an arbitrary selectable mathematical choice. Thus, in representative embodiments, X_opt computation block 204 determines X_opt from phi and pi, exponent ratio block 210 reflects the disclosed ratio 7/3, and Delta N_eff computation block 212 produces the fixed value according to Delta N_eff=X_opt\hat{ }(7/3)=(phi/pi)\hat{ }(7/3). In one preferred numerical embodiment, fixed-decimal representation block 214 stores Delta N_eff as 0.212628491279. In another preferred embodiment, N_eff_total computation block 216 determines N_eff_total=3.044+Delta N_eff, which may be represented as 3.256628491279.

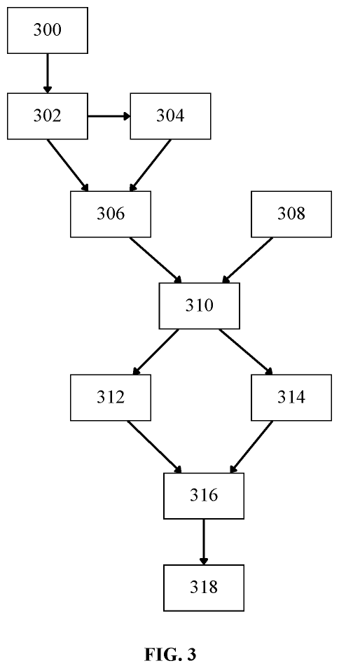

Referring to FIG. 3, a software-library and solver-patch embodiment is shown. Library module 300 may expose callable function 302 backed by stored constant 304. CAMB patch generator 306 and CLASS patch generator 308 may produce initialization or configuration file output 310 or may directly prepare patch artifacts for patched CAMB execution 312 and patched CLASS execution 314. Result collector 316 may collect solver outputs, and logging and verification module 318 may record value provenance, patch status, tolerance checks, or solver-to-solver comparisons.

FIG. 3 illustrates preferred embodiments rather than the broadest required architecture. In one embodiment, library module 300 is a local software library exposing callable function 302 that returns Delta N_eff and/or N_eff_total. In another embodiment, stored constant 304 contains a precomputed representation of the disclosed fixed value. In another embodiment, CAMB patch generator 306 identifies an assignment or parameter field that would otherwise accept a sampled or user-variable Delta N_eff or N_eff value and substitutes the disclosed fixed value instead. In another embodiment, CLASS patch generator 308 performs an analogous replacement for CLASS-related parameter assignments. Initialization or configuration file output 310 illustrates a concrete fallback artifact embodiment in which the invention is expressed through a machine-readable configuration rather than direct source modification. Patched CAMB execution 312 and patched CLASS execution 314 show downstream solver operation using the fixed value in place of a sampled parameter.

Referring to FIG. 4, a free-parameter replacement and chain-simplification workflow is shown. Conventional parameter set 400 includes sampled Delta N_eff branch 402 and repeated solver evaluation path 404. Deterministic Delta N_eff substitution block 406 replaces that sampled branch with a disclosed fixed value by setting Delta N_eff or N_eff_total through a configuration, initialization artifact, runtime parameter object, or patch mechanism prior to a solver run, thereby yielding fixed-parameter set 408 and reduced-dimension chain block 410. In one embodiment, the substitution comprises removing Delta N_eff from a sampled parameter vector used by a Markov chain Monte Carlo workflow such that Delta N_eff is not explored as an independent posterior axis during execution. Posterior generation block 412 may then operate without sampling Delta N_eff as an independent axis. Reproducibility output 414 and compute-savings output 416 illustrate workflow consequences that may arise from use of the disclosed substitution architecture.

FIG. 4 is a useful illustration of the core operational effect of the invention. The invention is not merely publication of a number. Rather, deterministic Delta N_eff substitution block 406 uses the disclosed fixed value in place of a free Delta N_eff parameter in a target chain or solver workflow. In representative embodiments, this may remove a sampling dimension, eliminate a Delta N_eff marginalization step, constrain the chain to a fixed Delta N_eff value, reduce repeated solver evaluations attributable to that axis, or improve reproducibility across analyses that otherwise would have treated Delta N_eff as a free variable. Such consequences are advantageous but need not be required in every claimed embodiment.

Referring to FIG. 5, an optional network-service embodiment is shown. Client device 500 communicates with request handler 502, which may route requests through REST interface 504 or gRPC interface 506 to deterministic value engine 508. Response formatter 510 may return Delta N_eff field 512, N_eff_total field 514, and metadata field 516. Optional auth and rate-limit module 518 may provide deployment-level controls. FIG. 5 is expressly subordinate to the core invention and illustrates one optional wrapper around the relation-driven deterministic generator.

In one embodiment of FIG. 5, deterministic value engine 508 computes the disclosed relation at request time. In another embodiment, deterministic value engine 508 retrieves a stored constant previously derived from the disclosed relation. Response formatter 510 may output machine-readable objects, including structured text such as JSON, typed RPC responses, or other network payloads. Delta N_eff field 512 may carry the fixed Delta N_eff value. N_eff_total field 514 may carry the optional total N_eff value. Metadata field 516 may carry X_opt, formula, or precision information. Optional auth and rate-limit module 518 is not part of the core inventive concept and should not be read to limit embodiments that omit such deployment features.

Referring to FIG. 6, an optional hardware and fixed-point accelerator embodiment is shown. Host processor 600 may access constant store 602 and optional fixed-point arithmetic block 604, write the resulting value to output register 606, and provide it through interface bus 612 to downstream compute consumer 614. In some embodiments, the function may be implemented in FPGA fabric 608 or ROM embodiment 610. Verification comparator 616 may compare the hardware-produced value against another implementation, such as a CPU or floating-point reference. FIG. 6 is also subordinate to the core invention and shows optional implementation classes rather than core requirements.

In representative embodiments of FIG. 6, constant store 602 may hold the disclosed Delta N_eff constant and optionally the disclosed N_eff_total constant. Fixed-point arithmetic block 604 may be omitted where the constant is simply stored and returned, or may be present where one or more stages compute or format the value. FPGA fabric 608 and ROM embodiment 610 illustrate optional accelerator and hardware-storage paths. Downstream compute consumer 614 may be any consumer that accepts the fixed value, including a local solver, hardware pipeline, or hybrid computation engine. Verification comparator 616 may enforce acceptance criteria such as agreement within a stated tolerance.

Referring to FIG. 7, downstream cosmology applications of deterministic generator output 700 are shown. These include CMB analysis module 702, BAO forecast module 704, damping-tail comparison module 706, cross-code comparison module 708, reproducibility module 710, and validation reporting module 712. FIG. 7 is included to preserve downstream embodiments while making clear that such applications remain subordinate to the core deterministic generator. The invention is not the downstream analytics platform itself.

In one embodiment, deterministic generator output 700 is consumed by CMB analysis module 702 to perform parameter estimation or spectrum computation using the fixed Delta N_eff value. In another embodiment, BAO forecast module 704 uses the value in forecasting or comparative cosmological analyses. In another embodiment, damping-tail comparison module 706 compares outcomes corresponding to the disclosed fixed value against a standard baseline. Cross-code comparison module 708 may compare independent solver outputs using the same fixed value.

Reproducibility module 710 may quantify repeatability across environments or research groups. Validation reporting module 712 may aggregate and present such downstream results. None of these downstream modules alters the core identity of the invention.

Referring to FIG. 8, demonstrated and prophetic validation pathways are shown. Demonstrated implementation branch 800 includes Planck-style reanalysis branch 802, CLASS integration branch 804, and multi-code cross-check branch 806. Prophetic branches include CMB-S4 branch 808, high-l test branch 810, cross-platform verification branch 812, and service stress-test branch 814. Result classification block 816 distinguishes demonstrated support from prophetic or future-facing support. FIG. 8 is particularly useful for preserving support-level discipline in the specification.

In one embodiment, result classification block 816 is a conceptual classification rather than a software component. Its function is to make explicit that some disclosed material corresponds to concretely instantiated or computationally demonstrated embodiments, while other disclosed material corresponds to projected validation pathways, future measurements, future scaling campaigns, or future extensions. This distinction is important for written-description clarity and prosecution discipline. For example, numerical value generation, patch embodiments, and certain worked examples may be treated as demonstrated support, whereas CMB-S4 discrimination and some future observational or high-l preference testing may be treated as prophetic.

Computational examples involving numerical generation, solver integration, patch-based substitution, and cross-code comparison are therefore distinguished in this specification from future observational confirmation pathways, which are preserved without being presented as already reduced to practice.

As used herein, “N_eff” refers to an effective number of neutrino species or effective relativistic-radiation-content parameter used in cosmology workflows.

As used herein, “Delta N_eff” refers to an effective extra-radiation contribution beyond a baseline Standard Model contribution.

As used herein, “N_eff_total” refers to the sum of a baseline Standard Model value and Delta N_eff. In disclosed embodiments, the baseline Standard Model value is taken as 3.044.

As used herein, “X_opt” refers to the recognition-coverage optimum defined by X_opt=phi/pi.

As used herein, “fixed” means that the supplied Delta N_eff value is not sampled as a free parameter during the relevant cosmology computation, is not marginalized as an independent axis during such computation, and is not posterior-dependent.

As used herein, “deterministic” means that the disclosed Delta N_eff value is determined from the disclosed closed-form relation rather than selected by empirical fitting during the relevant solver or chain execution.

As used herein, “parameter-free” is used in the sense of the disclosed materials, namely that the Delta N_eff contribution is derived from phi and pi through X_opt and the disclosed exponent relation, rather than being introduced as a free empirical parameter in the computation pipeline.

In one embodiment, integration is verified by (i) confirming that a target solver or parameter-estimation engine does not sample Delta N_eff as an independent axis during execution, and (ii) confirming that a stored constant, configuration value, patch insertion, or runtime parameter object is used to set Delta N_eff or N_eff_total prior to computation of one or more cosmological observables. In one embodiment, the verification comprises logging an effective Delta N_eff value used during the run and recording an indication that Delta N_eff was fixed rather than sampled.

In one embodiment, the verification further comprises confirming that the effective Delta N_eff value logged during the solver run matches a predetermined reference value within a predetermined tolerance. In one embodiment, the predetermined reference value is 0.212628491279 and the predetermined tolerance is selected based on an output representation format used by the cosmology computation system.

In the disclosed framework, the recognition-coverage optimum is defined as: X_opt=phi/pi.

The effective extra-radiation contribution is then defined as: Delta N_eff=X_opt\hat{ }(7/3)=(phi/pi)\hat{ }(7/3).

Using phi=(1+sqrt(5))/2 and pi=3.141592653589793. . . , one obtains:
X_opt=0.5150362148004839 . . .
Delta N_eff=0.2126284912794069 . . .

In convenient fixed-decimal embodiments, Delta N_eff may be represented as: Delta N_eff=0.212628491279 with a disclosed absolute error smaller than approximately 5×10\hat{ }−13.

In embodiments that output or consume total effective neutrino-species contribution rather than Delta N_eff directly, the total value may be represented as: N_eff_total=3.044+Delta N_eff=3.2566284912794069 . . . and in convenient fixed-decimal embodiments: N_eff_total=3.256628491279.

In the disclosed framework, the exponent 7/3 is presented as corresponding to a ratio g_R/D, where g_R is an effective recognition-radiation degree count and D is the number of spatial dimensions. In the disclosed materials:
g_R=7
D=3
and therefore:
g_R/D=7/3.

The disclosed materials further present the exponent relation as: Delta N_eff =X_opt\hat{ }(g_R/D)=X_opt\hat{ }(7/3).

Accordingly, the specification preserves the disclosed framing that the exponent 7/3 is a load-bearing part of the derivation structure, rather than a merely optional exponent chosen for convenience. Likewise, the disclosed X_opt relation is preserved as load-bearing.

The disclosed invention may be practiced in embodiments requiring no runtime mathematical input, in embodiments that compute the disclosed relation during execution, and in embodiments that retrieve a previously stored representation of the disclosed value. In one class of embodiments, the relevant mathematical inputs are phi and pi, from which X_opt and Delta N_eff are determined. In another class of embodiments, Delta N_eff has already been computed according to the disclosed closed-form relation and is stored for later supply to a target computation system.

As illustrated generally in FIGS. 1-3, runtime inputs, where present, may include one or more of: a request for Delta N_eff, a request for N_eff_total, a request for a selected precision, a request for a selected output format, a solver target identifier, a chain-engine target identifier, or a request for generation of a patch artifact, configuration artifact, initialization artifact, or machine-readable response object. Such inputs affect packaging and delivery of the disclosed value, not the identity of the disclosed value itself.

Outputs may include one or more of: the fixed Delta N_eff value, the total N_eff value, the X_opt value, formula metadata, precision metadata, a machine-readable response object, a patch artifact, a configuration file, an initialization file, a stored constant table entry, a callable function result, a firmware-associated value, or a solver-ready parameter object. In downstream embodiments, outputs may additionally include one or more computed cosmology observables, reports, comparison artifacts, or validation results derived from use of the fixed value.

In representative workflows, operation may proceed through a plurality of stages. In a first stage, the system determines or stores X_opt. In a second stage, the system determines or stores Delta N_eff according to Delta N_eff=X_opt\hat{ }(7/3). In a third stage, the system optionally determines N_eff_total=3.044+Delta N_eff. In a fourth stage, the system selects an output mode, such as Delta N_eff-only mode, N_eff_total-only mode, or dual-output mode. In a fifth stage, the system supplies the fixed value to a target computation system. In a sixth stage, the target system executes a fixed-parameter computation using the supplied value in place of a sampled Delta N_eff parameter. These stages may be separated, combined, reordered, or partially omitted depending on embodiment, provided that the target computation uses the disclosed fixed value in place of a free Delta N_eff parameter.

As shown in FIG. 1 and further illustrated in FIGS. 2-6, the disclosed subject matter may be organized into a plurality of conceptual modules. These modules are disclosed to facilitate make-and-use understanding and do not necessarily imply separate physical components in every embodiment.

A derivation module determines X_opt and/or Delta N_eff from the disclosed closed-form relation. In one embodiment, the derivation module performs arithmetic operations corresponding to X_opt=phi/pi followed by exponentiation to the 7/3 power. In another embodiment, the derivation module may associate a stored constant with the disclosed formula for provenance, validation, or metadata purposes.

A constant-storage module stores Delta N_eff and optionally N_eff_total. The storage may be implemented as a compile-time constant, a runtime constant, a variable, a literal in source code, a configuration-field value, a database entry, a lookup-table entry, a ROM entry, or another machine-readable representation. The constant-storage module is particularly useful in embodiments where it is desirable to avoid repeated runtime computation of the same fixed value.

An interface module exposes the disclosed value to one or more consumers. Interface types include callable software functions, libraries, configuration or initialization outputs, patch artifacts, service responses, register outputs, bus interfaces, or direct parameter-setting mechanisms. In one embodiment, the interface module corresponds to local software interface 110 of FIG. 1. In another embodiment, the interface module corresponds to network interface 112. In another embodiment, the interface module corresponds to solver integration interface 114.

An integration module inserts, writes, transmits, or otherwise supplies the disclosed value to a target system. The integration module may modify a source assignment, generate a patch, write a configuration file, create an initialization file, populate a runtime parameter object, return a value to an SDK call, or write a value to a hardware-visible register or memory location. In preferred embodiments, the integration module causes a target solver or chain to use the disclosed fixed value in place of a sampled Delta N_eff parameter.

An output module provides one or more outputs, including the fixed Delta N_eff value, N_eff_total, metadata, patch artifacts, configuration files, logs, verification results, or downstream analysis artifacts. In one embodiment, the output module corresponds to response formatter 510 of FIG. 5. In another embodiment, the output module corresponds to result collector 316 of FIG. 3.

An optional validation module may compare one implementation against another, check fixed-decimal tolerance, verify solver acceptance of the fixed value, or record solver-to-solver agreement. In one embodiment, the optional validation module corresponds to logging and verification module 318 of FIG. 3 or verification comparator 616 of FIG. 6. The validation module is useful, but is not required in every embodiment.

The core invention does not require probabilistic scoring, empirical model selection, posterior comparison, threshold voting, or ranking logic to determine Delta N_eff. The disclosed Delta N_eff value is fixed by the stated closed-form relation. However, implementation logic may determine how the fixed value is packaged and supplied to a target system.

In one embodiment, if a target system accepts Delta N_eff directly, the system outputs Delta N_eff. In another embodiment, if a target system accepts only total N_eff, the system outputs N_eff_total. In another embodiment, if the target can accept either form, the system outputs either or both according to a configuration setting, compile-time selection, runtime option, request parameter, or predetermined default.

With respect to precision, embodiments may include full-precision floating-point computation, precomputed decimal representation, fixed-decimal representation, fixed-point representation, or any representation that maintains the disclosed value within an acceptable tolerance for the intended use. In preferred decimal embodiments, Delta N_eff may be represented as 0.212628491279 and N_eff_total as 3.256628491279. In one preferred numerical embodiment, Delta N_eff is represented as 0.212628491279 with an absolute error less than approximately 5×10\hat{ }−13 relative to the closed-form expression Delta N_eff=(phi/pi)\hat{ }(7/3). In corresponding embodiments, N_eff_total is represented as 3.256628491279. These decimal embodiments are useful in fixed-decimal, fixed-point, patch-based, configuration-based, initialization-based, and machine-readable deployment forms.

Useful fallback embodiments include, without limitation: a stored constant table, a source-code patch artifact, a machine-readable configuration object, an initialization file, a non-transitory computer-readable medium storing instructions, and a response object carrying the deterministic value. These fallback forms should be preserved because they provide concrete claim positions if broader computation-centric claim language is challenged.

Referring again to FIG. 3, in one preferred embodiment the disclosed value is exposed through local library module 300. Library module 300 may be written in C, C++, Python, or another suitable language and may expose callable function 302 that returns Delta N_eff and/or N_eff_total. In one preferred lightweight embodiment, library module 300 is header-only or otherwise minimal. In one example, the implementation is smaller than approximately 20 source lines exclusive of packaging boilerplate. In another embodiment, the library is packaged as an installable module, wheel, SDK element, or command-line utility. In another example, a Python package or wheel exposes a callable interface that returns Delta N_eff and optionally N_eff_total. These examples are illustrative of concrete software forms and do not limit broader embodiments in which the deterministic effective-radiation contribution is supplied through another local software mechanism.

Stored constant 304 may contain a precomputed representation of the disclosed value. In one embodiment, stored constant 304 is compiled directly into source or object code. In another embodiment, stored constant 304 is retrieved at runtime from local storage, configuration, memory, or another machine-readable source. The invention is not limited to any particular software language, packaging scheme, or calling convention.

In one preferred CAMB integration embodiment, CAMB patch generator 306 identifies a source assignment or parameter pathway that would otherwise accept a sampled or user-variable Delta N_eff or N_eff value and substitutes the disclosed fixed value instead. In representative embodiments, the substituted value may comprise Delta N_eff=0.212628491279 or, where the target pathway accepts total N_eff rather than Delta N_eff directly, N_eff_total=3.256628491279. In one disclosed example, a parameter assignment is replaced with N_eff=3.044+0.212628491279. In some embodiments, the modification is implemented by changing a single assignment line or a small set of associated initialization statements in a target solver file. In a representative make-and-use path, the system identifies a target file or assignment site, locates the relevant parameter-assignment expression, substitutes the fixed constant or total value, stores the modified file or parameter object, and executes the solver using the fixed value. These examples are illustrative of concrete integration paths and do not limit broader embodiments in which the disclosed deterministic value is supplied through another solver-integration mechanism.

In one preferred CLASS integration embodiment, CLASS patch generator 308 performs an analogous substitution for a CLASS-related parameter assignment. In representative embodiments, the substituted value may comprise Delta N_eff=0.212628491279 or, where the target pathway accepts total N_eff rather than Delta N_eff directly, N_eff_total=3.256628491279. In one disclosed example, CLASS patch generator 308 sets pba->Neff to 3.044+0.212628491279. In some embodiments, the modification is implemented by changing a single assignment line or a small set of associated initialization statements in a target solver file. As with CAMB, the substitution may be performed by direct source modification, generated patch, preprocessing, configuration generation, initialization-file generation, runtime assignment, or another suitable integration path. These examples are illustrative and do not limit broader embodiments in which the disclosed deterministic value is supplied through another CLASS-related integration mechanism.

Initialization or configuration file output 310 illustrates a concrete fallback artifact embodiment in which the invention is expressed through a machine-readable file or object rather than direct source modification. This embodiment is strategically useful because it anchors the invention in concrete artifacts that can be generated, stored, transmitted, and used in practice without requiring manual source-code editing.

Patched CAMB execution 312 and patched CLASS execution 314 represent downstream solver operations performed using the fixed disclosed value. Result collector 316 may capture solver outputs, posteriors, spectra, forecast quantities, comparison files, or logs generated from such execution. Logging and verification module 318 may record the provenance of the fixed value, precision or tolerance checks, and cross-solver agreement.

Referring again to FIG. 5, network and service embodiments are optional wrappers around the core relation-driven invention. In one embodiment, client device 500 transmits a request to request handler 502, which routes the request through REST interface 504 or gRPC interface 506 to deterministic value engine 508. Deterministic value engine 508 then computes or retrieves the disclosed fixed value and provides it to response formatter 510, which returns one or more machine-readable fields, such as Delta N_eff field 512, N_eff_total field 514, and metadata field 516.

In one embodiment, deterministic value engine 508 computes the disclosed relation at request time. In another embodiment, deterministic value engine 508 retrieves a previously stored representation of the disclosed value. In still another embodiment, the service returns both a numeric field and explanatory metadata indicating the formula, X_opt, or precision. In one illustrative service embodiment, a response object includes a Delta N_eff field, an N_eff_total field, a formula field, an X_opt field, and a precision field, or a combination thereof. In one example, the service exposes a REST endpoint corresponding to /dNeff and a gRPC analogue. In one illustrative deployment embodiment, p95 response latency is approximately 0.4 ms, a container image is approximately 15 MB, memory footprint is approximately 16 MB per container, and service-level availability is approximately 99.99%. These metadata and deployment features are optional and should not be understood as central to the invention or required in all embodiments.

The foregoing deployment and performance values are representative implementation targets and examples, and are not required in all embodiments unless expressly recited. In some embodiments, the deterministic value engine returns a stored constant and therefore executes in constant time relative to request size, while in other embodiments the deterministic value engine computes the disclosed closed-form relation at runtime; in either case, the disclosed fixed-value substitution remains the same.

Optional auth and rate-limit module 518 illustrates deployment-level controls such as authentication, authorization, rate limiting, or operational throttling. Containerization, memory-footprint control, service-level targets, and other deployment details may also be used in some service embodiments. Such features remain subordinate to the core invention and should not be treated as necessary limitations unless separately recited in a narrower claim.

Referring again to FIG. 6, optional hardware embodiments may provide the disclosed fixed value to a downstream consumer through processor-based, fixed-point, FPGA, ROM, or related hardware structures. In one embodiment, host processor 600 accesses constant store 602 and returns the stored value without runtime exponentiation. In another embodiment, fixed-point arithmetic block 604 formats the stored value into a fixed-point representation and optionally verifies the formatted value against a reference within a predetermined tolerance prior to writing it to output register 606. In another embodiment, FPGA fabric 608 contains logic for providing the value to downstream compute consumer 614 over interface bus 612, including embodiments in which the value is stored in ROM or block RAM and presented on a bus in response to a request. In yet another embodiment, ROM embodiment 610 stores a machine-readable representation of the disclosed value for later retrieval.

Verification comparator 616 may compare a hardware-produced value to a reference implementation, such as a CPU floating-point implementation or a prevalidated decimal reference, to confirm agreement within a specified tolerance. In one hardware embodiment, the deterministic effective-radiation contribution is represented in 32-bit fixed-point form. In one FPGA-based embodiment, throughput is at least 5×10\hat{ }8 evaluations per second at power not exceeding approximately 8 W. In one illustrative implementation, the hardware path uses approximately 256 DSP resources, approximately 12 BRAM resources, and approximately 9k LUT resources. These values are illustrative optional embodiments that provide concrete support for accelerator implementations and do not alter the identity of the invention, which remains the fixed relation-driven provision of the disclosed Delta N_eff value.

The disclosed fixed value may be integrated into one or more of: Boltzmann solvers, parameter-estimation chains, forecast engines, local numerical environments, notebooks, SDKs, scheduling tools, or research workflows. In preferred embodiments, the integration causes a target computation to use the fixed disclosed value in place of a sampled Delta N_eff parameter. In downstream embodiments, such integration may support CMB parameter estimation, BAO forecasting, damping-tail comparison, or reproducibility workflows. Such downstream applications remain subordinate to the core deterministic generator and substitution mechanism.

To strengthen written-description support and preserve fallback positions, the disclosure expressly includes embodiments in which the invention is embodied in one or more concrete artifacts. Examples include: a source-code patch, a diff or patch artifact, a configuration file, an initialization file, a stored constant table, a callable library, a non-transitory computer-readable medium, a machine-readable response object, firmware instructions, and a bitstream-associated constant artifact where supported.

These artifacts may be generated automatically or manually, may be stored locally or remotely, and may be consumed directly by a solver or by an intermediary integration tool. The invention therefore includes not only arithmetic determination of the fixed value, but also preparation of concrete machine-usable artifacts that cause a target system to use the fixed value instead of sampling Delta N_eff.

As illustrated in FIG. 4, use of the disclosed fixed value can replace a free Delta N_eff axis with a deterministic value. In example workflows described in the source materials, this may reduce effective chain dimensionality, reduce repeated solver evaluations attributable to Delta N_eff exploration, improve cross-group reproducibility, and simplify operational cosmology analyses. In one representative example, a parameter-estimation workflow is reduced from a 7-parameter chain including Delta N_eff to a 6-parameter chain in which Delta N_eff is no longer independently sampled. In another representative example, convergence may be achieved with approximately 30% fewer samples, yielding a corresponding reduction in solver evaluations and wall-clock time. These are valuable computational consequences of the disclosed substitution architecture. They are not, however, required to define the broadest embodiments, which are satisfied whenever the disclosed fixed value is used in place of a sampled Delta N_eff parameter in a target computation.

The disclosed materials identify machine-checked formal-verification support for the disclosed relation and associated properties. In a preferred support embodiment, the formalization is associated with the file RecognitionDeltaNeff.lean, identified in the disclosed materials as IndisputableMonolith/Applied/RecognitionDeltaNeff.lean, and includes proofs, proof objects, or machine-checkable support corresponding to one or more of derivation from phi, positivity, boundedness, numeric realization, parameter-free status, evaluation-speed support, and hardware-throughput support. Illustrative theorem names or proof objects may include dneff_from_phi, dneff_positive, dneff_small, dneff_numeric, parameter_free_count, parameter_free, eval_ultrafast, and fpga_throughput. Such formal support may additionally be associated with equivalent formal artifacts, derivative proof objects, or machine-checkable verification packages that preserve the disclosed relation and supporting properties.

This formal support is strategically important because it reinforces the exactness of the disclosed relation, the positivity and boundedness of the value, the numeric result, the parameter-free character of the disclosed substitution, and, in some embodiments, evaluation-speed and hardware-throughput support associated with concrete implementation classes. Such material is appropriately placed in the written-description and support sections of the specification and may be used to support fallback claim strategy. Formal verification is not required in every implementation embodiment unless expressly recited in a claim.

Validation may occur at multiple levels. In one class of embodiments, a correct implementation is accepted if it returns Delta N_eff within a specified numeric tolerance of the disclosed value. In another class of embodiments, a correct integration is accepted if a target solver or chain executes using the fixed value in place of a sampled Delta N_eff parameter. In another class of embodiments, cross-platform validation may compare CPU, GPU, FPGA, or multiple software implementations. In another class of embodiments, solver-to-solver validation may compare outputs obtained from multiple Boltzmann solvers configured with the same fixed value.

As illustrated conceptually in FIG. 8, present implementation support should be distinguished from future observational validation. Numerical generation, fixed-decimal embodiments, solver patch embodiments, configuration or initialization artifact embodiments, and cross-code computational examples may be treated as implemented or concretely instantiated support. By contrast, future observational discrimination, future CMB-S4 confirmation or refutation, some future high-l preference determinations, and some future large-scale service or hardware stress tests should be treated as prophetic or future-facing support rather than present reduction to practice. Result classification block 816 is useful for maintaining that distinction.

Optional and alternative embodiments include Delta N_eff-only mode, N_eff_total-only mode, dual-output mode, metadata-rich response mode, compile-time determination, runtime retrieval, local supply, remote supply, floating-point implementation, fixed-point implementation, and hardware-backed supply. These branches alter implementation form, not the identity of the invention. In each case, the target system still receives and uses the same disclosed fixed value or an equivalent representation thereof.

Prophetic embodiments include, without limitation: temperature-dependent Delta N_eff(T); decomposition of the disclosed Delta N_eff contribution into component species or helicity contributions; joint forecasting with tensor-to-scalar ratio or lensing modules; on-chip combinations with other RS-or RP-related constant providers; and expanded cosmology-stack integrations. These embodiments are preserved for future flexibility but are not treated as the present core invention. They should remain clearly identified as prophetic or future-facing unless and until more specific implementation support is developed.

The disclosed invention may yield one or more output products, including: a numeric Delta N_eff output, a numeric N_eff_total output, a machine-readable data object, a patch file, a configuration file, an initialization artifact, stored software instructions, a callable library result, a firmware artifact, or a hardware-associated output value. Such output products are useful both for implementation and for claim support across multiple statutory classes.

Advantages of the disclosed invention include deterministic operation, fixed closed-form value generation, parameter-free substitution of Delta N_eff in the disclosed sense, replacement of a sampled parameter with a machine-suppliable constant, minimal integration surface in preferred patch embodiments, reproducible use across independent groups and codebases, and portability across software, service, and optional hardware implementations. Performance figures, throughput values, latency values, and future observational implications, where disclosed, should be understood as supportive examples or optional embodiment details rather than universal requirements.

1. A computer-implemented method for operating a cosmology computation pipeline, comprising: determining or accessing a deterministic effective-radiation contribution according to Delta N_eff=X_opt\hat{ }(7/3), where X_opt=phi/pi; supplying the deterministic effective-radiation contribution, or a total effective neutrino-species value derived therefrom, to a cosmology computation system; and executing, by the cosmology computation system, a cosmology computation using the deterministic effective-radiation contribution, or the total effective neutrino-species value derived therefrom, as a fixed input in place of a sampled Delta N_eff parameter.

2. The method of claim 1, wherein the deterministic effective-radiation contribution is given by:
Delta N_eff=(phi/pi)\hat{ }(7/3).

3. The method of claim 1, wherein the deterministic effective-radiation contribution is fixed, not sampled, not marginalized, and not posterior-dependent during execution of the cosmology computation.

4. The method of claim 1, further comprising determining a total effective neutrino-species value according to: N_eff_total=3.044+Delta N_eff, and supplying N_eff_total to the cosmology computation system.

5. The method of claim 4, wherein Delta N_eff is approximately 0.212628491279 and N_eff_total is approximately 3.256628491279.

6. The method of claim 1, wherein the cosmology computation system comprises a Boltzmann solver, a parameter-estimation engine, or both.

7. The method of claim 6, wherein the Boltzmann solver comprises CAMB or CLASS.

8. The method of claim 1, wherein supplying the deterministic effective-radiation contribution comprises generating or modifying a source-code patch, a configuration file, an initialization file, or a runtime parameter object that causes the cosmology computation system to use the deterministic effective-radiation contribution, or a total effective neutrino-species value derived therefrom, in place of the sampled Delta N_eff parameter.

9. The method of claim 1, wherein determining the deterministic effective-radiation contribution comprises computing X_opt from phi and pi and exponentiating X_opt to a 7/3 power, or retrieving a stored machine-readable representation of the deterministic effective-radiation contribution.

10. The method of claim 1, wherein supplying the deterministic effective-radiation contribution comprises modifying a CAMB assignment such that N_eff=3.044+0.212628491279 or modifying a CLASS assignment such that pba->Neff is set to 3.044+0.212628491279.

11. The method of claim 1, wherein executing the cosmology computation comprises omitting a Delta N_eff sampling step by removing Delta N_eff from a sampled parameter vector used by a Markov chain Monte Carlo workflow such that Delta N_eff is not explored as an independent posterior axis during the computation.

12. A cosmology computation system, comprising: one or more processors; and one or more memory devices storing instructions that, when executed by the one or more processors, cause the system to: determine or access a deterministic effective-radiation contribution according to Delta N_eff =X_opt\hat{ }(7/3), where X_opt=phi/pi; supply the deterministic effective-radiation contribution, or a total effective neutrino-species value derived therefrom, to a cosmology computation engine; and operate the cosmology computation engine using the deterministic effective-radiation contribution, or the total effective neutrino-species value derived therefrom, as a fixed input in place of a sampled Delta N_eff parameter.

13. The system of claim 12, wherein the cosmology computation engine comprises a Boltzmann solver, a parameter-estimation engine, a forecast engine, or a combination thereof, and the system further comprises an integration module configured to generate a patch artifact, a configuration file, an initialization file, or a runtime parameter object for the cosmology computation engine.

14. The system of claim 12, wherein the system comprises a network interface configured to return a machine-readable response object including a Delta N_eff field and optionally one or more of: an N_eff_total field, a formula field, an X_opt field, and a precision field.

15. The system of claim 12, wherein the deterministic effective-radiation contribution is represented in fixed-point form and provided by FPGA logic at a throughput of at least 5×10\hat{ }8 evaluations per second and a power of not more than approximately 8 W.

16. The system of claim 12, wherein the deterministic effective-radiation contribution is supplied with p95 latency of approximately 0.4 ms or less, in a container image of approximately 15 MB or less, with memory usage of approximately 16 MB per container or less.

17. A non-transitory computer-readable medium storing instructions that, when executed by one or more processors, cause the one or more processors to: determine or access a deterministic effective-radiation contribution according to Delta N_eff=X_opt\hat{ }(7/3), where X_opt=phi/pi;
supply the deterministic effective-radiation contribution, or a total effective neutrino-species value derived therefrom, to a cosmology computation system; and cause the cosmology computation system to execute a cosmology computation using the deterministic effective-radiation contribution, or the total effective neutrino-species value derived therefrom, as a fixed input in place of a sampled Delta N_eff parameter.

18. The non-transitory computer-readable medium of claim 17, wherein the instructions are embodied in a header-only library, a package, a stored constant table, a configuration object, an initialization file, a patch artifact, or a machine-readable response object generator.

19. The non-transitory computer-readable medium of claim 17, wherein the instructions cause the one or more processors to generate a modified solver file, parameter file, configuration file, or initialization file in which a sampled Delta N_eff variable is replaced by the deterministic effective-radiation contribution or by a total effective neutrino-species value derived therefrom.

20. The method of claim 1, wherein executing the cosmology computation comprises reducing a parameter-estimation workflow from a 7-parameter chain including Delta N_eff to a 6-parameter chain that omits Delta N_eff as an independently sampled axis.
